(19) United States
(12) Patent Application Publication
(10) Pub. No.: US 2004/0212606 A1
(43) Pub. Date: Oct. 28, 2004

(54) Self-luminous image display apparatus

(76) Inventors: Koichi Miyachi, Kyoto (JP); Motohiro Yamahara, Nara (JP); Yoshihiro Izumi, Nara (JP)

Correspondence Address: EDWARDS & ANGELL, LLP, P.O. BOX 55874, BOSTON, MA, 02205, US

(21) Appl. No.: 10/488,132

(22) PCT Filed: Sep. 19, 2002
(86) PCT No.: PCT/JP02/09651

(30) Foreign Application Priority Data
Oct. 1, 2001 (JP) 2001-304987

(51) Int. Cl. G09G 5/00

(52) U.S. Cl. 345/204

(57) ABSTRACT

A self-luminous image display apparatus A includes an output section 10 for displaying an image, a reflection section 20 provided on a rear side of the output section 10 with a reflective surface thereof facing the output section, and a light-emitting section 30 provided on a rear side of the output section 10. The output section 10 includes a linear polarization device 15 provided so as to cover a display surface for transmitting only predetermined linearly-polarized light of ambient light, and a retardation film 14 provided closer to the light-emitting section than the linear polarization device 15 for turning linearly-polarized light coming from a direction normal to the display surface and transmitted through the linear polarization device 15 into circularly-polarized light. The retardation film 14 has a structure forming a refractive index ellipsoid having a refractive index of nx in a slow axis direction, a refractive index of ny in a fast axis direction and a refractive index of nz in a film thickness direction, while satisfying a relationship of nx>nz>ny.

### TECHNICAL FIELD

The present invention relates to a self-luminous image display apparatus.

### BACKGROUND ART

An organic electroluminescence display (hereinafter referred to as “organic EL display”) is an application of the phenomenon that an organic thin film having a thickness of about 1 μm emits light when a current is injected into the organic thin film, and it has been actively researched and developed in recent years. A typical structure of the organic EL display is a layered structure including an output-side substrate 10′, a reflection-side substrate 20′ and an organic EL light-emitting layer 30′ interposed between the substrates 10′ and 20′, as illustrated in FIG. 7A. The output-side substrate 10′ includes an output-side substrate body 11′, a transparent electrode 12′ made of ITO (Indium Tin Oxiside) provided on the inner side of the output-side substrate body 11′, and a hole injection/transfer layer 13′ provided on the inner side of the transparent electrode 12′. The reflection-side substrate 20′ includes a reflection-side substrate body 21′ and a metal electrode 22′ made of aluminum. In an organic EL display having such a structure, a portion of light from the organic EL light-emitting layer 30′, which emits light omnidirectionally, that travels toward the output-side substrate 10′ is output directly from the output-side substrate 10′, while another portion of the light that travels toward the reflection-side substrate 20′ is output indirectly from the output-side substrate 10′ after being reflected by the metal electrode 22′ having a mirror surface, thus efficiently taking out the light emitted from the organic EL light-emitting layer 30′.

An organic EL display has a problem as follows when it is used under the sunlight or in the presence of room light, as is a portable telephone, or the like. That is, when ambient light such as the sunlight or room light enters the organic EL display through the output-side substrate, the ambient light is reflected by the metal electrode and is output through the output-side substrate, and the contrast of the organic EL display is lowered significantly by the ambient light reflection.

To address this problem, JP 8-321381 A and JP 9-127885 A each disclose an organic EL display in which a ¼ wave plate (retardation film) 14′ and a linear polarization plate 15′ are provided in this order on the output-side substrate 10′ so that the polarization axis (transmission axis) of the linear polarization plate 15′ is at an angle of 45° with respect to the slow axis of the ¼ wave plate 14′, as illustrated in FIG. 7B. With the displays disclosed in these publications, half of the ambient light is blocked by the linear polarization plate 15′. The linearly-polarized light of the remaining half of the ambient light transmitted through the linear polarization plate 15′ is turned into circularly-polarized light (e.g., right-handed circularly-polarized light) by the ¼ wave plate 14′, and then passes through a transparent electrode, after which it is turned into circularly-polarized light of the reverse direction (right-handed circularly-polarized light being turned into left-handed circularly-polarized light) as it is reflected by the metal electrode 22′. Then, the circularly-polarized light of the reverse direction is turned into linearly-polarized light by the ¼ wave plate. However, the polarization axis of the linearly-polarized light has been rotated by 90° with respect to that of the original linearly-polarized light, whereby the linearly-polarized light is blocked by the linear polarization plate 15′. Therefore, all of the ambient light incident on the organic EL display is blocked by the linear polarization plate 15′, thus preventing the reflection of the ambient light from entering the viewer's eye, thereby preventing the contrast from being lowered by the ambient light reflection.

However, while such a structure as described above is generally effective for suppressing the ambient light reflection for light that is coming from around the direction normal to the organic EL display, it is not necessarily sufficient for suppressing the ambient light reflection for light that is coming from an inclined direction. Therefore, there is a problem that the contrast is significantly low when the user views the organic EL display from an inclined direction.

An object of the present invention is to provide a self-luminous image display apparatus providing a high-contrast display performance even when viewed from an inclined direction.

Note that as a technique characterized by its retardation film, JP 2000-47030 A discloses a circular polarization plate arranged while being inclined by a certain angle with respect to the incident light about the absorption axis or the transmission axis of a linear polarization plate as the rotation axis, wherein the angle between the rotation axis and the slow axis of the retardation plate (retardation film) satisfies a predetermined relationship. The publication states that with such an arrangement, the circular polarization plate sufficiently functions as a circular polarization plate even when inclined about the absorption axis or the transmission axis of the circular polarization plate as the rotation axis or when inclined about the slow axis or the fast axis of the retardation plate as the rotation axis. Moreover, the publication discloses, as retardation plates of examples of the invention, a retardation plate satisfying the relationship of nx>ny>nz, a retardation plate satisfying the relationship of nx=nz>ny, and a retardation plate satisfying the relationship of nx>ny=nz, where nx is the refractive index in the slow axis direction, ny is the refractive index in the fast axis direction, and nz is the refractive index in the film normal direction. Furthermore, the publication discloses a retardation plate satisfying the relationship of nx>ny>nz as a retardation plate of a reference example.

Moreover, JP 2000-19518 A discloses a liquid crystal display apparatus in which a retardation compensation device is provided between at least one of a pair of polarization plates and a liquid crystal cell, the retardation compensation device satisfying the relationship of nx>ny>nz, where nx is the refractive index in the slow axis direction, ny is the refractive index in the fast axis direction, and nz is the refractive index in the film normal direction. The publication states that with such an arrangement, the gray level inversion can be prevented for any viewing directions.

### DISCLOSURE OF THE INVENTION

According to the present invention, the retardation film functions as a ¼ wave plate even when viewed from an inclined direction.

Specifically, the present invention provides a self-luminous image display apparatus, including an output section for displaying an image, a reflection section provided on a rear side of the output section with a reflective surface thereof facing the output section, and a light-emitting section provided on a rear side of the output section, wherein:

the output section includes a linear polarization device provided so as to cover a display surface for transmitting only predetermined linearly-polarized light of ambient light, and a retardation film provided closer to the light-emitting section than the linear polarization device for turning linearly-polarized light coming from a direction normal to the display surface and transmitted through the linear polarization device into circularly-polarized light; and

the retardation film has a structure forming a refractive index ellipsoid having a refractive index of nx in a slow axis direction (x axis direction), a refractive index of ny in a fast axis direction (y axis direction) perpendicular to the slow axis direction (x axis direction) and a refractive index of nz in a film thickness direction (z axis direction), while satisfying a relationship of nx>nz>ny.

The present invention also provides a self-luminous image display apparatus, including an output-side substrate, a reflection-side substrate provided so as to oppose the output-side substrate, and a light-emitting layer provided so as to be interposed between the substrates, wherein light from the light-emitting layer is output directly from the output-side substrate and is output indirectly from the output-side substrate after being reflected by the reflection-side substrate, wherein:

the output-side substrate includes a linear polarization device provided so as to cover a display surface for transmitting only predetermined linearly-polarized light of ambient light, and a retardation film provided closer to the light-emitting layer than the linear polarization device for turning linearly-polarized light coming from a direction normal to the display surface and transmitted through the linear polarization device into circularly-polarized light; and

the retardation film has a structure forming a refractive index ellipsoid having a refractive index of nx in a slow axis direction (x axis direction), a refractive index of ny in a fast axis direction (y axis direction) perpendicular to the slow axis direction (x axis direction) and a refractive index of nz in a film thickness direction (z axis direction), while satisfying a relationship of nx>nz>ny.

With such an arrangement, the retardation film has a structure forming a refractive index ellipsoid, i.e., a biaxial retardation film is used, and the film satisfies the relationship of nx>nz>ny, whereby the retardation thereof for an inclined viewing angle is close to ¼ the wavelength of visible light. Therefore, the ambient light reflection from the inclined viewing angle is blocked, and it is possible to obtain a high-contrast display performance not only when viewed from the normal direction but also when viewed from an inclined direction.

The self-luminous image display apparatus is not limited to an organic EL display, or the like, but may alternatively be a hybrid display apparatus using a liquid crystal display apparatus in combination with an organic EL display, or the like.

In the present invention, it is preferred that the retardation film satisfies the following expression, where d is the thickness of the film, i.e., it is preferred that the retardation R2 of the retardation film in the film thickness direction is equal to or greater than a value obtained by dividing the film-in-plane retardation R1 of the retardation film by 137.5 nm and multiplying the obtained value with −42 nm and is less than or equal to a value obtained by dividing the film-in-plane retardation R1 by 137.5 nm and multiplying the obtained value with 28 nm.

$$\frac{d ( nx - ny )}{137.5} \times ( - 42 ) ≦ R 2 = d ( \frac{nx + ny}{2} - nz ) ≦ \frac{d ( nx - ny )}{137.5} \times 28$$

With such an arrangement, it is possible to obtain a display performance with a contrast equal to or greater than 10, with which no problems occur in practical use, even for an inclined viewing angle of 60 degrees.

Moreover, in the present invention, it is preferred that the retardation film satisfies the following expression, i.e., it is preferred that the retardation R2 of the retardation film in the film thickness direction is equal to or greater than a value obtained by dividing the film-in-plane retardation R1 of the retardation film by 137.5 nm and multiplying the obtained value with −18 nm and is less than or equal to a value obtained by dividing the film-in-plane retardation R1 by 137.5 nm and multiplying the obtained value with 5 nm.

$$\frac{d ( nx - ny )}{137.5} \times ( - 18 ) ≦ R 2 = d ( \frac{nx + ny}{2} - nz ) ≦ \frac{d ( nx - ny )}{137.5} \times 5$$

With such an arrangement, it is possible to obtain a display performance with a contrast equal to or greater than 15 even for an inclined viewing angle of 60 degrees.

Furthermore, in the present invention, it is more preferred that the retardation film satisfies the following expression, i.e., it is more preferred that the retardation R2 of the retardation film in the film thickness direction is 0.

$$R 2 = d ( \frac{nx + ny}{2} - nz ) = 0$$

With such an arrangement, the retardation is substantially constant for any inclined viewing angle over the entire 360° azimuth angles, whereby it is possible to obtain a high-contrast display performance that is substantially constant for any inclined viewing angle over the entire 360° azimuth angles.

In the present invention, while it is ideal that the film-in-plane retardation R1 of the retardation film is 137.5 nm, i.e., ¼ of 550 nm, which is the middle wavelength of visible light, it is preferred in practice that the retardation R1 is 119 to 157 nm as shown in the following expression.

119≦R1=d(nx−ny)≦157

With such an arrangement, it is possible to obtain a display performance with a contrast equal to or greater than 20, with which no problems occur in practical use, when viewed from the normal direction.

Moreover, in the present invention, it is preferred that the film-in-plane retardation R1 of the retardation film is 130 to 145 nm as shown in the following expression.

130≦R1=d(nx−ny)≦145

With such an arrangement, it is possible to obtain a display performance with a contrast equal to or greater than 100, which is considered to be a high display quality, when viewed from the normal direction.

The self-luminous image display apparatus of the present invention is particularly effective for apparatuses that may be used under the sunlight, such as apparatuses whose display mode is an electroluminescence display mode or a field emission display mode. Herein, the electroluminescence display mode includes both the organic EL display mode and the inorganic EL display mode.

Other objects, features, and advantages of the present invention will become apparent from the following description taken in conjunction with the accompanying drawings.

### BRIEF DESCRIPTION OF THE DRAWINGS

FIG. 1 is a schematic cross-sectional view illustrating an organic EL display A according to an embodiment of the present invention.

FIG. 2 illustrates the positional relationship between a linear polarization plate and a retardation film.

FIG. 3 illustrates the results of evaluation for the contrast of an organic EL display using a retardation film of Example 1 with respect to the azimuth angle and the viewing angle.

FIG. 4 illustrates the results of evaluation for the contrast of an organic EL display using a retardation film of Example 2 with respect to the azimuth angle and the viewing angle.

FIG. 5 is a graph illustrating the relationship between the retardation R2 of the retardation film in the thickness direction and the contrast when viewed from the viewing angle of 60°.

FIG. 6 is a graph illustrating the relationship between the in-plane retardation R1 of the retardation film and the contrast as viewed from the normal direction.

FIG. 7A and FIG. 7B are each a schematic cross-sectional view illustrating a conventional organic EL display.

### BEST MODE FOR CARRYING OUT THE INVENTION

An embodiment of the present invention will now be described in detail with reference to the drawings.

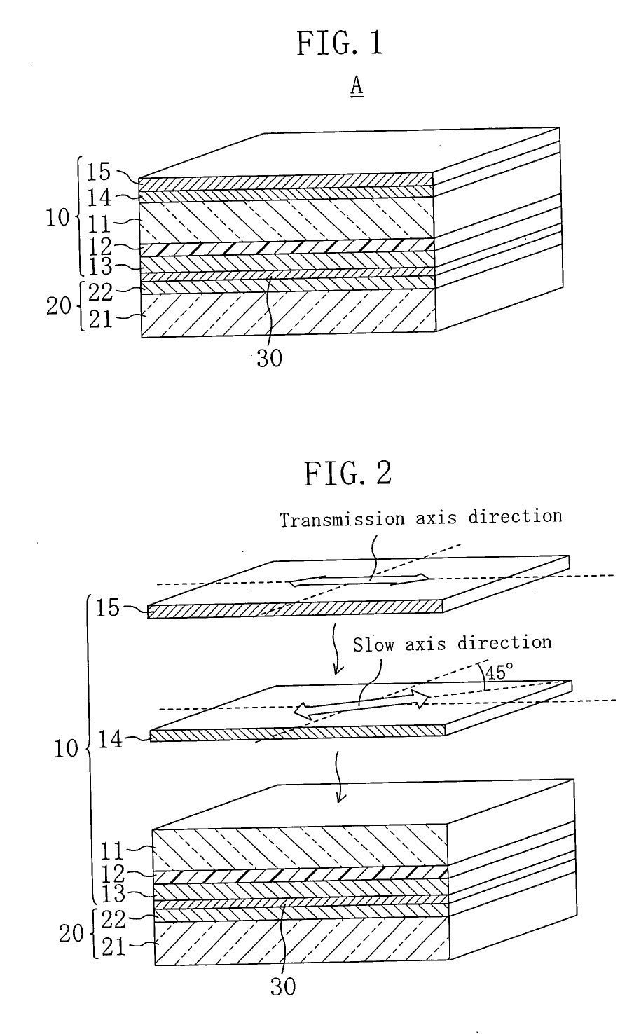

FIG. 1 schematically illustrates a cross section of an organic EL display A, which is a self-luminous image display apparatus according to an embodiment of the present invention.

The organic EL display A includes an output-side substrate (output section) 10, a reflection-side substrate (reflection section) 20 opposing the output-side substrate 10, and an organic EL light-emitting layer (light-emitting section) 30 interposed between the substrates 10 and 20. In other words, the organic EL light-emitting layer 30 is provided on the rear side of the output-side substrate 10, and the reflection-side substrate 20 is provided on the rear side of the organic EL light-emitting layer 30.

The output-side substrate 10 includes an output-side substrate body 11 being a glass plate, a transparent electrode 12 being an anode and a hole injection/transfer layer 13 layered in this order on the inner side of the output-side substrate body 11, and a retardation film 14 and a linear polarization plate (linear polarization device) 15 layered in this order on the outer side of the output-side substrate body 11. The output-side substrate 10 is for displaying an image.

The transparent electrode 12 on the inner side of the output-side substrate body 11 is made of ITO (Indium Tin Oxiside), or the like, and is for injecting holes into the hole injection/transfer layer 13. Moreover, the transparent electrode 12 includes a plurality of pixel electrodes arranged in a lattice pattern and each defining one pixel. Each pixel electrode is provided with a switching device such as a TFT (Thin Film Transistor). Thus, the organic EL display A is an active matrix mode.

The hole injection/transfer layer 13 is made of a phthalocyanine compound, an aromatic amine compound, or the like, and is for transferring holes injected from the transparent electrode 12 to the organic EL light-emitting layer 30.

The retardation film 14 is formed as a film biaxially drawn in two directions and having a thickness of d, and has a structure forming a refractive index ellipsoid having a refractive index of nx in the slow axis direction, a refractive index of ny in the fast axis direction and a refractive index of nz in the film thickness direction, while satisfying the relationship of nx>nz>ny. Moreover, the film-in-plane retardation R1 of the retardation film 14 is 119 to 157 nm (more preferably 130 to 145 nm), as shown in the following expression.

119≦R1=d(nx−ny)≦157

(130≦R1=d(nx−ny)≦145)

Furthermore, the retardation R2 of the retardation film 14 in the film thickness direction is 0 nm, as shown in the following expression.

$$R 2 = d ( \frac{nx + ny}{2} - nz ) = 0$$

Moreover, the linear polarization plate 15 is provided in the form of a film and is a device having a function of transmitting only light of a particular oscillation direction (polarization axis direction). The retardation film 14 and the linear polarization plate 15 are arranged so that the slow axis of the retardation film 14 and the transmission axis of the linear polarization plate 15 are at an angle of 45°, as illustrated in FIG. 2. In this way, linearly-polarized light that is coming from the direction normal to the display surface and transmitted through the linear polarization plate 15 can be turned into circularly-polarized light by the retardation film 14.

The reflection-side substrate 20 includes a reflection-side substrate body 21 being a glass plate, and a metal electrode 22 being a cathode and common electrode layered on the inner side of the reflection-side substrate body 21.

The metal electrode 22 on the inner side of the reflection-side substrate body 21 is made of aluminum, magnesium, or the like, is formed with a mirror surface, and is for injecting electrons into the organic EL light-emitting layer 30.

The organic EL light-emitting layer 30 is a thin film having a thickness of about 1 μm and made of an organic phosphor such as an aromatic cyclic compound or a heterocyclic compound, and emits light upon recombination of electrons from the metal electrode 22 and holes from the transparent electrode 12 and the hole injection/transfer layer 13.

In the organic EL display A having such an arrangement, as a DC voltage is applied between the metal electrode 22 being an anode and the transparent electrode 12 being a cathode, electrons are injected into the organic EL light-emitting layer 30 from the metal electrode 22 while holes are injected into the organic EL light-emitting layer 30 from the transparent electrode 12 via the hole injection/transfer layer 13, and the electrons and the holes are recombined together to emit light of a predetermined wavelength. The light emission is omnidirectional, and a portion of the light that travels toward the output-side substrate 10 is output directly from the output-side substrate 10, while another portion of the light that travels toward the reflection-side substrate 20 is output indirectly from the output-side substrate 10 after being reflected by the metal electrode 22, thus efficiently taking out the light emitted from the organic EL light-emitting layer 30.

Moreover, half of ambient light such as the sunlight or room light that is coming from the direction normal to the display surface is blocked by the linear polarization plate 15, while the linearly-polarized light of the remaining half of the ambient light passing through the linear polarization plate 15 is turned into circularly-polarized light (e.g., right-handed circularly-polarized light) by the ¼ wave plate 14, and then passes through the inside, after which it is turned into circularly-polarized light of the reverse direction (right-handed circularly-polarized light being turned into left-handed circularly-polarized light) as it is reflected by the mirror-surfaced metal electrode 22 facing the output-side substrate 10. Then, the circularly-polarized light of the reverse direction passes again through the inside to reach the retardation film 14, where it is turned into linearly-polarized light. However, the polarization axis of the linearly-polarized light has been rotated by 90° with respect to that of the original linearly-polarized light, whereby the linearly-polarized light is blocked by the linear polarization plate 15. In this way, all of the ambient light that is coming from the direction normal to the display surface of the organic EL display A is blocked by the linear polarization plate 15, thus preventing the ambient light reflected by the metal electrode 22 from being output.

Furthermore, since a biaxial film is used as the retardation film 14 and it satisfies the relationship of nx>nz>ny, the retardation in an inclined viewing angle is closer to ¼ the wavelength of visible light, whereby the ambient light reflection coming from the inclined viewing angle is also blocked as with the mechanism of blocking the ambient light reflection coming from the direction normal to the display surface. Thus, it is possible to obtain a high-contrast display performance not only when viewed from the normal direction but also when viewed from an inclined direction.

Moreover, since the retardation R2 of the retardation film 14 in the film thickness direction is 0 nm, it is possible to obtain a display performance with a contrast equal to or greater than 10, with which no problems occur in practical use, even in an inclined viewing angle of 60 degrees, while the retardation in an inclined viewing angle is substantially constant over the entire 360° azimuth angles. Therefore, it is possible to obtain a high-contrast display performance in an inclined viewing angle over the entire 360° azimuth angles.

Moreover, since the film-in-plane retardation R1 of the retardation film 14 is 119 to 157 nm, it is possible to obtain a display performance with a contrast equal to or greater than 20, with which no problems occur in practical use, when viewed from the normal direction. Furthermore, when the film-in-plane retardation R1 of the retardation film 14 is 130 to 145 nm, it is possible to obtain a display performance with a contrast equal to or greater than 100, which is considered to be a high display quality, when viewed from the normal direction.

Note that while the organic EL display A is used as the self-luminous image display apparatus in the embodiment above, the present invention is not limited to this, but may alternatively be used in an inorganic EL display, a plasma display, a cold-cathode tube display, a light-emitting diode display, a field emission display, or the like, or may be used in a hybrid display apparatus using a self-luminous image display apparatus in combination with a liquid crystal display apparatus. With any of these displays, the present invention can be very effective when the display is used under the sunlight.

Moreover, while the retardation film 14 is a retardation film whose retardation R2 in the film thickness direction is 0 nm in the embodiment above, the present invention is not limited to this. As long as it satisfies the following expression, it is possible to obtain a display performance with a contrast equal to or greater than 10, with which no problems occur in practical use, even when viewed from an inclined viewing angle of 60 degrees.

$$\frac{d ( nx - ny )}{137.5} \times ( - 42 ) ≦ R 2 = d ( \frac{nx + ny}{2} - nz ) ≦ \frac{d ( nx - ny )}{137.5} \times 28$$

Furthermore, if it satisfies the following expression, it is possible to obtain a display performance with a contrast equal to or greater than 15 even when viewed from an inclined viewing angle of 60 degrees.

$$\frac{d ( nx - ny )}{137.5} \times ( - 18 ) ≦ R 2 = d ( \frac{nx + ny}{2} - nz ) ≦ \frac{d ( nx - ny )}{137.5} \times 5$$

Moreover, while the organic EL display A is an active matrix mode in the embodiment above, the present invention is not limited to this, but may alternatively be used in a passive matrix mode or a segment mode.

Moreover, an electron injection/transfer layer, which is not provided in the embodiment above, may alternatively be provided between the metal electrode 22 and the organic EL light-emitting layer 30.

Moreover, in a case where a film of triacetylcellulose, or the like, is used as the support material of the polarization layer of the linear polarizer, the film functions as a retardation film having negative uniaxial optical anisotropy. In such a case, it is not necessarily optimal to set the retardation R2 of the retardation film 14 in the film thickness direction to be 0 nm, but the values nx, ny and nz need to be adjusted while taking into consideration the presence of the support material film.

Tests

Test 1

Tested Samples

The following two different retardation films were provided.

### EXAMPLE 1

A retardation film having a biaxial optical anisotropy obtained by biaxially drawing a polymer film in two directions was used as Example 1. The film-in-plane retardation R1 of the retardation film of Example 1 was 135 nm and the retardation R2 thereof in the film thickness direction was 0 nm, as shown in the following expression, and the retardation film satisfied the relationship of nx>nz>ny, where nx is the refractive index in the slow axis direction, ny is the refractive index in the fast axis direction, nz is the refractive index in the film thickness direction, and d is the thickness of the film.

R1=d(nx−ny)=135

$$R 2 = d ( \frac{nx + ny}{2} - nz ) = 0$$

### EXAMPLE

A retardation film having a uniaxial optical anisotropy obtained by uniaxially drawing a polymer film in one direction was used as Example 2. The film-in-plane retardation R1 of the retardation film of Example 2 was 135 nm and the retardation R2 thereof in the film thickness direction was 67.5 nm, as shown in the following expression, and the retardation film satisfied the relationship of nx>nz=ny, where nx is the refractive index in the slow axis direction, ny is the refractive index in the fast axis direction, nz is the refractive index in the film thickness direction, and d is the thickness of the film.

R1=d(nx−ny)=135

$$R 2 = d ( \frac{nx + ny}{2} - nz ) = 67.5$$

Test Method

Organic EL displays were provided with the retardation films of Examples 1 and 2 attached to the surfaces of the output-side substrates and with linear polarization plates attached to the retardation films. Each of the organic EL displays was provided so that the slow axis of the retardation film and the transmission axis of the linear polarization plate were at an angle of 45°.

The organic EL displays using the retardation films of Examples 1 and 2 were viewed for viewing angles (polar angles) of 0 to 80° over the entire 360° azimuth angles for qualitative contrast evaluation. Note that the viewing angle is the angle in which the display is viewed with respect to the direction normal to the display surface. The organic EL displays were evaluated with a circle symbol denoting a good contrast, a triangle symbol denoting a slightly lower contrast that causes no problems in practical use, and a cross symbol denoting a low contrast that causes problems in practical use.

Test Results

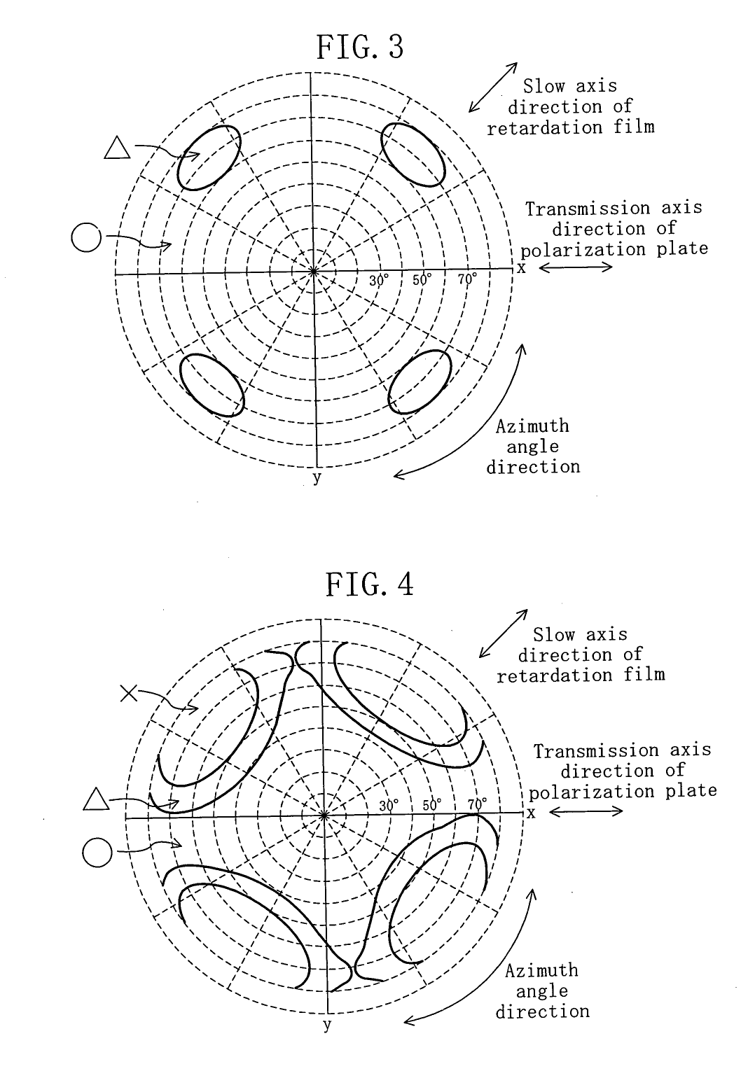

FIG. 3 is a map of the results of evaluation for the contrast where the retardation film of Example 1 is used with respect to the azimuth angle and the viewing angle. FIG. 4 is equivalent to FIG. 3 where the retardation film of Example 2 is used.

It can be seen from FIG. 3 that the contrast is generally high even though there are areas labeled with the triangle symbol over an azimuth angle of about 300 in the viewing angle range of 60 to 80° in the slow axis direction and in the fast axis direction. In contrast, it can be seen from FIG. 4 that the high-contrast region is generally small, and there are areas labeled with the cross symbol over an azimuth angle of about 600 in the viewing angle range of 60 to 80° in the slow axis direction and in the fast axis direction, with areas labeled with the triangle symbol surrounding the areas labeled with the cross symbol. It is believed that the reason is as follows. The retardation film of Example 1 is a biaxial film where nx>nz>ny, and the retardation thereof is close to ¼ the wavelength when viewed from an inclined direction. Therefore, the retardation film effectively functions as a ¼ wave plate not only when viewed from the normal direction but also when viewed from an inclined direction, thereby realizing a high-contrast display performance even when viewed from an inclined direction. On the other hand, the retardation film of Example 2 is a uniaxial film where nx>nz=ny. Therefore, the retardation film effectively functions as a ¼ wave plate primarily only when viewed from the normal direction.

Moreover, when the retardation film of Example 1 was used, it was possible to obtain a display performance with a substantially constant contrast for any inclined direction over the entire 360° azimuth angles. It is believed that this is because the retardation R2 of the retardation film in the film thickness direction is 0 nm, whereby the retardation is substantially constant for any inclined viewing angle over the entire 360° azimuth angles.

Test 2

Tested Samples

A plurality of retardation films were provided having a film-in-plane retardation R1 of 137.5 nm, i.e., ¼ of 550 nm, which is the middle wavelength of visible light, and having different nz values.

Test Method

Organic EL displays were provided with the retardation films attached to the surfaces of the output-side substrates and with linear polarization plates attached to the retardation films. Each of the organic EL displays was provided so that the slow axis of the retardation film and the transmission axis of the linear polarization plate were at an angle of 45°.

The contrast of each organic EL display was measured as viewed from an inclined viewing angle of 60°. Then, the retardation R2 of each retardation film in the film thickness direction was associated with the contrast thereof. Note that the retardation R2 in the film thickness direction can be represented by the following expression, where nx is the refractive index of the retardation film in the slow axis direction, ny is the refractive index in the fast axis direction, nz is the refractive index in the film thickness direction, and d is the thickness of the film.

$$R 2 = d ( \frac{nx + ny}{2} - nz )$$

Test Results

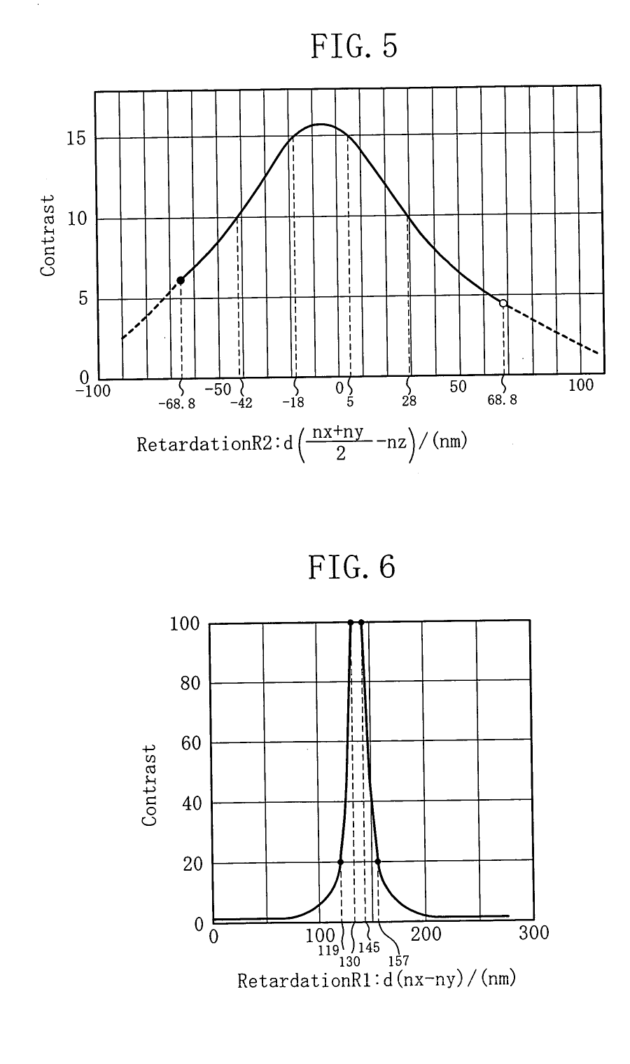

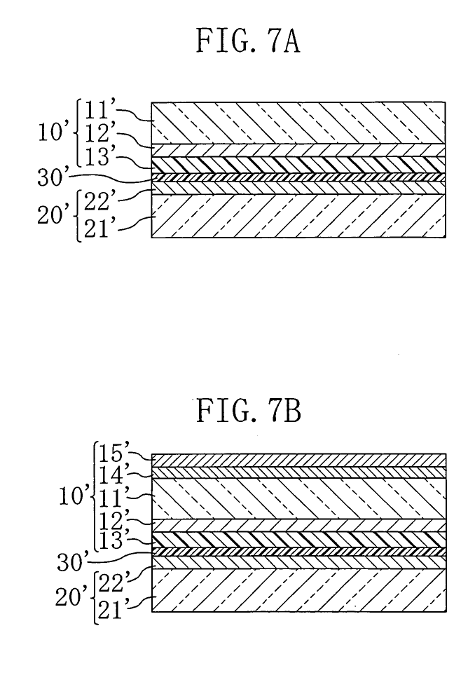

FIG. 5 illustrates the relationship between the retardation R2 of a retardation film in the film thickness direction and the contrast thereof as viewed from an inclined viewing angle of 60°. Herein, the retardation film whose retardation R2 in the film thickness direction is 68.8 nm is a uniaxial film where nx>ny=nz (open circle symbol in the figure). Moreover, the retardation film whose retardation R2 in the film thickness direction is −68.8 nm is a uniaxial film where nx=nz>ny (solid circle symbol in the figure). The retardation films whose retardation R2 in the film thickness direction is greater than −68.8 nm and less than 68.8 nm are biaxial films where nx>nz>ny (solid line in the figure), whereas the retardation films whose retardation R2 in the film thickness direction is less than −68.8 nm or greater than 68.8 nm are biaxial films where nx>ny>nz (broken line in the figure).

It can be seen from FIG. 5 that if the retardation R2 of the retardation film in the film thickness direction is greater than −68.8 nm and less than 68.8 nm, i.e., if the retardation film is a biaxial film where nx>nz>ny, it is possible to obtain a high-contrast display performance when viewed from an inclined direction. Specifically, it can be seen that it is possible to obtain a display performance with a contrast equal to or greater than 10, with which no problems occur in practical use, when the retardation R2 is in the range of −42 to 28 nm, and it is possible to obtain a display performance with a contrast equal to or greater than 15 when the retardation R2 is in the range of −18 to 5 nm.

While these results are for the case where the film-in-plane retardation R1 is 137.5 nm, the results can be generalized as follows. It is possible to obtain a display performance with a contrast equal to or greater than 10, with which no problems occur in practical use, when the retardation film satisfies the following expression.

$$\frac{d ( nx - ny )}{137.5} \times ( - 42 ) ≦ R 2 = d ( \frac{nx + ny}{2} - nz ) ≦ \frac{d ( nx - ny )}{137.5} \times 28$$

Moreover, it is possible to obtain a display performance with a contrast equal to or greater than 15 when the retardation film satisfies the following expression.

$$\frac{d ( nx - ny )}{137.5} \times ( - 18 ) ≦ R2 = d ( \frac{nx + ny}{2} - nz ) ≦ \frac{d ( nx - ny )}{137.5} \times 5$$

Test 3

Tested Samples

A plurality of retardation films were provided having different film-in-plane retardations R1.

Test Method

Organic EL displays were provided with the retardation films attached to the surfaces of the output-side substrates and with linear polarization plates attached to the retardation films. Each of the organic EL displays was provided so that the slow axis of the retardation film and the transmission axis of the linear polarization plate were at an angle of 45°.

The contrast of each organic EL display was measured as viewed from the normal direction. Then, the film-in-plane retardation R1 of each retardation film was associated with the contrast thereof. Note that the film-in-plane retardation R1 can be represented by the following expression, where nx is the refractive index of the retardation film in the slow axis direction, ny is the refractive index in the fast axis direction, and d is the thickness of the film.

R1=d(nx−ny)

Test Results

FIG. 6 illustrates the relationship between the film-in-plane retardation R1 of the retardation film and the contrast as viewed from the normal direction.

It can be seen from FIG. 6 that it is possible to obtain a display performance with a contrast of 20, with which no problems occur in practical use, when the retardation R1 is in the range of 119 to 157 nm, and it is possible to obtain a display performance with a contrast of equal to or greater than 100 when the retardation R1 is in the range of 130 to 145 nm.

### INDUSTRIAL APPLICABILITY

As described above, the self-luminous image display apparatus of the present invention is useful in providing a high-contrast display performance even when viewed from an inclined direction.

1. A self-luminous image display apparatus, comprising an output section for displaying an image, a reflection section provided on a rear side of the output section with a reflective surface thereof facing the output section, and a light-emitting section provided on a rear side of the output section, wherein:
the output section includes a linear polarization device provided so as to cover a display surface for transmitting only predetermined linearly-polarized light of ambient light, and a retardation film provided closer to the light-emitting section than the linear polarization device for turning linearly-polarized light coming from a direction normal to the display surface and transmitted through the linear polarization device into circularly-polarized light; and
the retardation film has a structure forming a refractive index ellipsoid having a refractive index of nx in a slow axis direction, a refractive index of ny in a fast axis direction and a refractive index of nz in a film thickness direction, while satisfying a relationship of nx>nz>ny.

2. The self-luminous image display apparatus of claim 1, wherein the retardation film satisfies the following expression, where d is a thickness of the film.
$$\frac{d ( nx - ny )}{137.5} \times ( - 42 ) ≦ d ( \frac{nx + ny}{2} - nz ) ≦ \frac{d ( nx - ny )}{137.5} \times 28$$

3. The self-luminous image display apparatus of claim 2, wherein the retardation film satisfies the following expression.
$$\frac{d ( nx - ny )}{137.5} \times ( - 18 ) ≦ d ( \frac{nx + ny}{2} - nz ) ≦ \frac{d ( nx - ny )}{137.5} \times 5$$

4. The self-luminous image display apparatus of claim 3, wherein the retardation film satisfies the following expression.
$$d ( \frac{nx + ny}{2} - nz ) = 0$$

5. The self-luminous image display apparatus of claim 1, wherein the retardation film satisfies the following expression, where d is a thickness of the film.
119≦d(nx−ny)≦157

6. The self-luminous image display apparatus of claim 5, wherein the retardation film satisfies the following expression.
130≦d(nx−ny)≦145

7. The self-luminous image display apparatus of claim 1, wherein a display mode of the self-luminous image display apparatus is an electroluminescence display mode or a field emission display mode.

8. A self-luminous image display apparatus, comprising an output-side substrate, a reflection-side substrate provided so as to oppose the output-side substrate, and a light-emitting layer provided so as to be interposed between the substrates, wherein light from the light-emitting layer is output directly from the output-side substrate and is output indirectly from the output-side substrate after being reflected by the reflection-side substrate, wherein:
the output-side substrate includes a linear polarization device provided so as to cover a display surface for transmitting only predetermined linearly-polarized light of ambient light, and a retardation film provided closer to the light-emitting layer than the linear polarization device for turning linearly-polarized light coming from a direction normal to the display surface and transmitted through the linear polarization device into circularly-polarized light; and
the retardation film has a structure forming a refractive index ellipsoid having a refractive index of nx in a slow axis direction, a refractive index of ny in a fast axis direction and a refractive index of nz in a film thickness direction, while satisfying a relationship of nx>nz>ny.

9. The self-luminous image display apparatus of claim 8, wherein the retardation film satisfies the following expression, where d is a thickness of the film.
$$\frac{d ( nx - ny )}{137.5} \times ( - 42 ) ≦ d ( \frac{nx + ny}{2} - nz ) ≦ \frac{d ( nx - ny )}{137.5} \times 28$$

10. The self-luminous image display apparatus of claim 9, wherein the retardation film satisfies the following expression.
$$\frac{d ( nx - ny )}{137.5} \times ( - 18 ) ≦ d ( \frac{nx + ny}{2} - nz ) ≦ \frac{d ( nx - ny )}{137.5} \times 5$$

11. The self-luminous image display apparatus of claim 10, wherein the retardation film satisfies the following expression.
$$d ( \frac{nx + ny}{2} - nz ) = 0$$

12. The self-luminous image display apparatus of claim 8, wherein the retardation film satisfies the following expression, where d is a thickness of the film.
119≦d(nx−ny)<157

13. The self-luminous image display apparatus of claim 12, wherein the retardation film satisfies the following expression.
130≦d(nx−ny)−≦145

14. The self-luminous image display apparatus of claim 8, wherein a display mode of the self-luminous image display apparatus is an electroluminescence display mode or a field emission display mode.
